(19) United States
(12) Patent Application Publication
(10) Pub. No.: US 2019/0243435 A1
(43) Pub. Date: Aug. 8, 2019

(54) ELECTRONIC DEVICES

(71) Applicant: AVNET ASIA PTE LTD., Singapore (SG)

(72) Inventors: Hui-Lung Chou, Taipei (TW); Chih-Hsiung Huang, Taipei (TW)

(21) Appl. No.: 16/204,755

(22) Filed: Nov. 29, 2018

Related U.S. Application Data
(60) Provisional application No. 62/626,965, filed on Feb. 6, 2018.

(51) Int. Cl. G06F 1/26; G06F 13/40; G01R 19/165; H02J 7/00; H02J 1/14

(52) U.S. Cl. CPC G06F 1/266; G06F 13/4022; G01R 19/16542; H02J 2001/008; H02J 1/14; H02J 2007/0062; H02J 7/0003

(57) ABSTRACT

An apparatus comprises a first port, a second port, a battery, and a power control unit electrically connected to the battery, the first port and the second port. The power control unit is configured to, on the basis of an output from the battery: transmit a first power signal to the first port and transmit a second power signal to the second port; or transmit a third power signal received by the first port to the second port.

### TECHNICAL FIELD

The present disclosure relates generally to electronic devices, more specifically to devices that can provide data and power communication.

### BACKGROUND

A hub expands the connection capability of an electronic device. An example is a USB hub, which allows multiple devices such as keyboard, mouse, memory and digital camera to be connected to one USB port of another device such as a laptop or a mobile phone.

A power bank is a mobile power source for electronic devices. The power bank can supply power to electronic devices such as laptops, mobile phones and tablets. The power bank can also charge the batteries of these electronic devices.

Modern consumers tend to carry more than one mobile device, such as one mobile phone and one tablet. Therefore, it would be inconvenient for them to additionally carry both a hub and a power bank. Moreover, the hub and the power bank come with individually dedicated cables, so carrying both the hub and the power bank results in carrying separate cables, causing inconvenience to the modern consumers.

### SUMMARY

In one or more embodiments, an apparatus is provided. The apparatus includes a first port, a second port, a battery, and a power control unit. The power control unit is electrically connected to the battery, the first port and the second port. The power control unit is configured to, on the basis of an output from the battery: transmit a first power signal to the first port and transmit a second power signal to the second port; or transmit a third power signal received by the first port to the second port.

In one or more embodiments, an apparatus is provided. The apparatus includes a first port, a second port, a power control unit, a battery, and a hub control unit. The power control unit is electrically connected to the first port and the second port. The battery is electrically connected to the power control unit. The hub control unit is electrically connected to the first port, the second port and the power control unit. The power control unit outputs a first voltage to the first port and a second voltage different from the first voltage to the second port.

### BRIEF DESCRIPTION OF THE DRAWINGS

Aspects of the present disclosure are best understood from the following detailed description when read with the accompanying figures. It is noted that various features may not be drawn to scale, and the dimensions of the various features may be arbitrarily increased or reduced for clarity of discussion.

FIG. 1 illustrates an electronic device in accordance with an embodiment of the present disclosure.

FIGS. 2A, 2B, 2C, 2D, 2E and 2F illustrate different usage scenarios and different embodiments in accordance with the present disclosure.

FIGS. 3A, 3B and 3C illustrate different usage scenarios and different embodiments in accordance with the present disclosure.

FIGS. 4A and 4B illustrate different usage scenarios and different embodiments in accordance with the present disclosure.

FIGS. 5A and 5B illustrate methods for determining which power source is used to power/charge which device in accordance with embodiments of the present disclosure.

FIG. 6 illustrates an electronic device in accordance with an embodiment of the present disclosure.

FIG. 7 illustrates an electronic device in accordance with an embodiment of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

Electronic devices often provide a single function. For example, a hub expands the connection capability of one port. A USB hub, for example, allows more than one device to be connected to one USB port. As another example, a power bank comprising a battery can supply power to other electronic devices in use. It can also charge the internal battery of the other electronic devices if one exists, no matter whether the other electronic devices are in use or not. The power bank can supply power via a standardized port, such as a USB port. The power bank can supply power via a non-standardized port. In some embodiments of the present disclosure, a port can carry data communication and power communication at the same time.

It is often desirable to have a device that provides more than one single function. For example, it would be advantageous to combine the functions of a hub and a power bank into one multi-functional device. The multi-functional device can reduce the number of devices that consumers have to carry while providing the same level of convenience. Moreover, the multi-functional device may reduce the number of cables that consumers have to carry in order to use different single-functional devices. In some embodiments, data communication with a hub and power communication with a power bank require different types of cables. In some embodiments, the multi-functional device uses a standardized interface for both data and power communication, thereby reducing the number of types of cables that consumers have to carry while they can still enjoy the same or nearly the same amount of convenience.

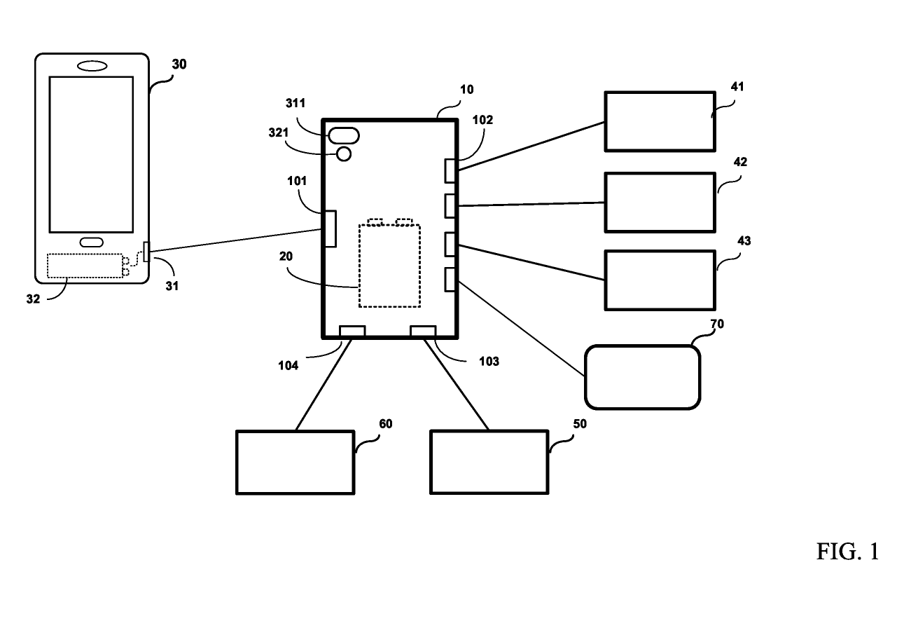

FIG. 1 illustrates an electronic device 10. The electronic device 10 includes a port 101, a port 102, a port 103, a port 104, a battery 20, an activation tool 311 and a signaling unit 321.

Each of the ports 101-104 may be connected to other devices. As illustrated in FIG. 1, the devices that may be connected to the electronic device 10 include, but are not limited to, devices 30, 41, 42, 43, 50 and 60. It is contemplated that the electronic device 10 may include more port(s) other than the ports 101-104 in accordance with some other embodiments of the present disclosure. It is contemplated that one or more of the ports 101-104 may be eliminated in accordance with some other embodiments of the present disclosure.

A charger 70 may also be connected to the electronic device 10. Although FIG. 1 shows that six devices 30, 41, 42, 43, 50 and 60 and a charger 70 may be connected to the electronic device 10, other numbers of devices that may be connected to the electronic device 10 are also possible, depending on the usage scenarios. In some embodiments, only one device is connected to the electronic device 10. In some embodiments, only one charger is connected to the electronic device 10. In some embodiments, two, three, four, five, six or more devices may be connected to the electronic device 10. In some embodiments, one or more chargers may be connected to the electronic device 10 in addition to any number of devices.

Ports 101, 102, 103, 104 may be identical, similar or different types of ports. Ports 101, 102, 103, 104 may carry data communication, power communication, or both. In some embodiments, some or all of ports 101, 102, 103, 104 may conform to standardized specifications, such as Universal Serial Bus (USB) specifications (including, but not limited to, USB 1.0, USB 1.1, USB 2.0, USB 3.0, USB 3.1, USB 3.2, USB Battery Charging 1.0, USB Battery Charging 1.1, USB Battery Charging 1.2, USB Power Delivery (PD) revision 1.0, USB PD revision 2.0, USB PD revision 3.0, USB Type-C 1.0, USB Type-C 1.1, and future revisions); different ports may conform to different versions of the same standardized specifications. In some embodiments, some or all of ports 101, 102, 103, 104 may be audio-visual interfaces, such as Video Graphics Array (VGA), High-Definition Multimedia Interface (HDMI), Digital Video Interface (DVI), Mini-DVI, Micro-DVI, and Mini DisplayPort (MiniDP). In some embodiments, ports 101, 102, 103, 104 may be of proprietary types and have customizable functionalities. In an embodiment, port 101 may be an upstream facing port (UFP), and port 102 may be a downstream facing port (DFP), and vice versa. In some embodiments, ports 101 and 102 are USB buses with each comprising the pins of (VBUS, C1/C2, D+/D−_1, D+/D−_2, SUB1/SUB2, USB3.0).

In the embodiment illustrated in FIG. 1, the device 30 may be a host device, such as a desktop, a laptop, a mobile phone, a smartphone, a tablet, and other devices that can be connected to port 101 via a port 31 of the device 30. The device 30 also comprises an internal battery 32. The device 30 can power itself by the internal battery 32, or receives power from external sources. The port 31 may be used for both data communication and power communication with ports of the electronic device 10, such as port 101. The internal battery 32 is rechargeable, for example, by external power sources via port 31. In some embodiments, the port 31 is a USB port.

Devices 41, 42, 43, 50 may be connected to ports 102, 103 and the other ports, and may be used for both data communication and power communication. Examples of devices 41, 42, 43, 50 include but are not limited to memories, hard drives, keyboards, computer mice, printers, digital cameras, flashlights, and ventilation fans. In some embodiments, devices 41, 42, 43, 50 may have USB interfaces supporting the same or different versions of the standardized specifications.

In some embodiments, the device 60 may be an external display, which may be connected to port 104 via an audio-visual interface or a USB interface or another standardized or proprietary interface.

The charger 70 may supply power to the electronic device 10 and, through the electronic device 10, to devices 41, 42, 43, 50 and 60. The charger 70 may be connected to AC/DC power outlets operating at voltages such as 110V and 220V, or to other sources of power.

The activation tool 311 may be controlled by the user of the electronic device 10 to activate a specific function. In some embodiments, the activation tool 311 is a button, which the user may press to activate the battery 20 to supply power to the devices connected to the electronic device 10. The activation tool 311 may have other physical appearances, such as a switch, a lever, a handle, and/or a sensor (such as an optical, audio, electrical. heat, and/or odor sensor).

The signaling unit 321 indicates a status of the electronic device 10. In some embodiments, the signaling unit 321 may be a light or a light emitting diode (LED). In some embodiments, the signaling unit 321 may indicate the level of the battery 20. For example, the signaling unit 321 may be configured to emit light with different colors or intensity to indicate different levels of the battery 20. As an example, the signaling unit 321 may be a one-color LED (which may be cheaper than multi-color light sources) that, when lit, indicates that a low battery level.

In accordance with an embodiment of the present disclosure, the device 30 is a smartphone connected to the port 101, the devices 41, 42, 43 are respectively a keyboard, a mouse and a loudspeaker, the device 50 is a USB memory stick, and the device 60 is a high-resolution external display 60. In this embodiment, devices 41, 42, 43, 50, 60 are connected to the port 31 of the device 30 through the electronic device 10, which in this case provides the function of a hub. Devices 41, 42, 43, 50, 60 may draw power from the smartphone 30, or, if the battery level is sufficient and the user activates the battery 20 by using the activation tool 311, from the battery 20. The electronic device 10 thus also provides the function of a power bank. In accordance with an embodiment of the present disclosure, the charger 70 is a power adaptor connected to a 110V indoor AC-power outlet (not shown) and is additionally connected to the electronic device 10. In this embodiment, the charger 70 may supply power to the devices 30, 41, 42, 43, 50, 60 and charge the battery 20 of the electronic device 10.

To further describe the functionalities of the electronic device 10, different usage scenarios and different embodiments in accordance with the present disclosure are provided below.

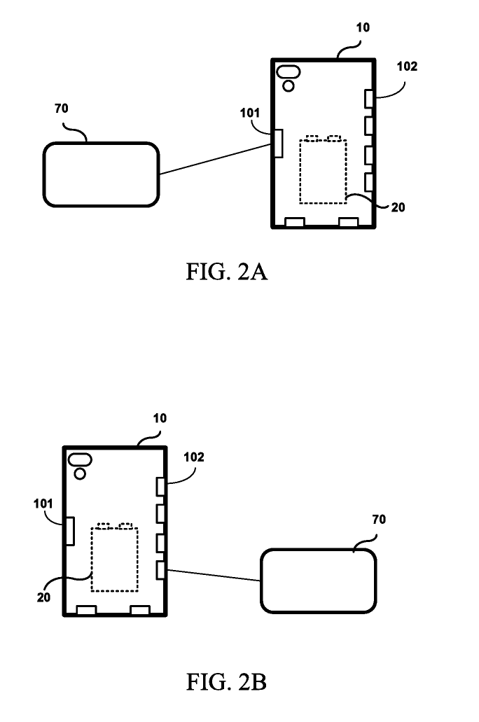

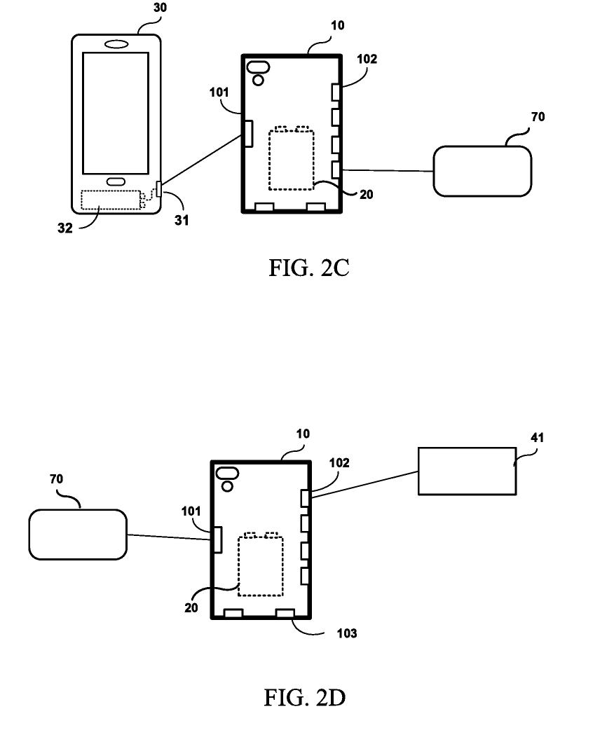

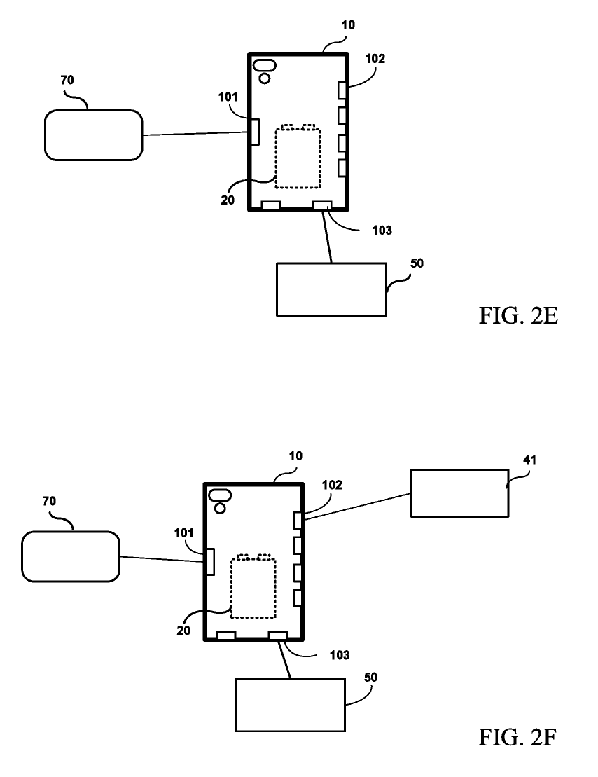

Refer to the usage scenario illustrated in FIG. 2A. Only the charger 70 is connected to the electronic device 10 via the port 101. The charger 70 may charge the battery 20 of the electronic device 10. The charger 70 may stop charging if the battery 20 is full.

Refer to the usage scenario illustrated in FIG. 2B. Only the charger 70 is connected to the electronic device 10 via the port 102. The charger 70 may charge the battery 20 of the electronic device 10 and may stop charging if the battery 20 is full. It would be clear from FIGS. 2A and 2B that ports 101 and 102 are both capable of power communication.

Refer to FIG. 2C, which depicts a scenario where both ports 101 and 102 are connected. A device 30 and a charger 70 are respectively connected to port 101 and port 102. The charger 70 may supply power to the device 30, or charge the internal battery 32 of the device 30, or do both. The charger 70 may charge the battery 20 of the electronic device 10. In some embodiments, the charger 70 may concurrently supply power to the device 30 and charge the battery 20. In some embodiments, the charger 70 may charge the battery 20 and the device 30 operates on its own internal battery 32. Other usages are also possible.

Refer to FIG. 2D, which depicts a scenario where both ports 101 and 102 are connected. A charger 70 and a device 41 are respectively connected to port 101 and port 102. The charger 70 may supply power to the device 41. The charger 70 may charge the battery 20 of the electronic device 10. In some embodiments, the charger 70 may concurrently supply power to the device 41 and charge the battery 20. In some embodiments, the charger 70 may supply power to the device 41 without charging the battery 20 of the electronic device 10. Other usages are also possible.

FIG. 2E is similar to FIG. 2D, so the possible operating conditions are not repeated. In some embodiments, ports 102 and 103 may have different capabilities, support different standards, or support different versions of the same standards, so a device 50 that can be connected to the port 103 may not be connected to the port 102 or may be connected to the port 102 under reduced functionality. For example, if the port 102 supports USB 3.0 and the port 103 supports USB 2.0, then USB 3.0-capable devices have to be connected to the port 102 in order to use the USB 3.0 functionalities. In some embodiments, the port 102 supports USB PD while the port 103 does not, in which case USB power delivery is not possible with the port 103.

FIG. 2F may be viewed as a scenario where the scenarios depicted in FIGS. 2D and 2E are combined. The charger 70 may charge the battery 20 of the electronic device 10. The charger 70 may supply power to the device 41. The charger 70 may supply power to the device 50. The charger 70 may charge the battery 20 of the electronic device 10 and supply power to the devices 41, 50. The charger 70 may supply power to the devices 41, 50 without charging the battery 20.

A charger 70 is connected to the electronic device 10 in all of the scenarios depicted in FIGS. 2A-2F. The charger 70 may charge the battery 20 of the electronic device 10, may supply power to devices connected to the electronic device 10, or may do both at the same time. In some embodiments, the electronic device 10 may be said to operate in a “charging mode” in the scenarios depicted in FIGS. 2A-2F.

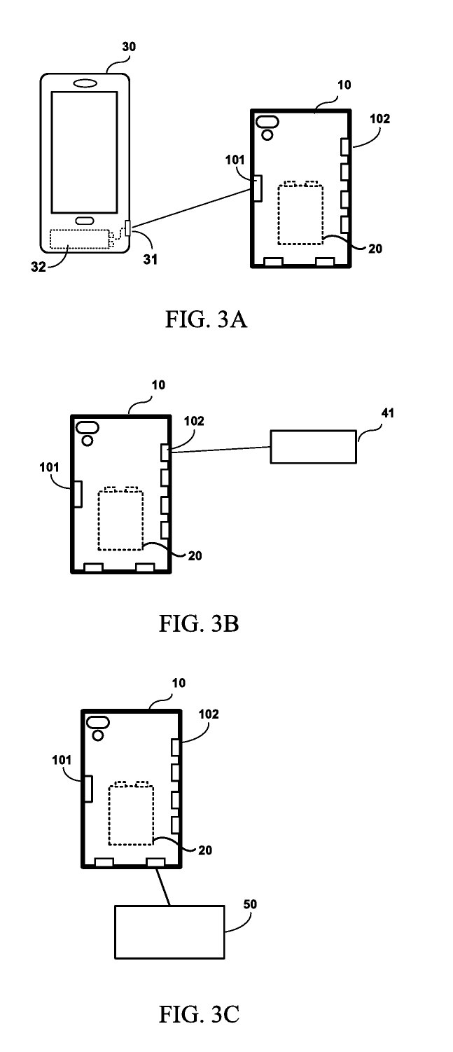

It is not necessary to connect a charger 70 to the electronic device 10 at all times; FIGS. 3A-3C depict exemplary scenarios.

Refer to FIG. 3A, where only a device 30 is connected to the electronic device 10. In some embodiments, the device 30 is a smartphone. The device 30 may receive power from the electronic device 10 if the level of the battery 20 is sufficient. The device 30 may operate on its own internal battery 32 regardless of whether the battery 20 has sufficient power. The user of the electronic device 10 may know the status of the battery 20 by the signaling unit 321. The user may choose to activate the charging function of the electronic device 10 by the activation tool 311, such as by pressing it to make the electronic device 10 supply power to the device 30. In some embodiments, the internal battery 32 of the device 30 may supply power to the battery 20 of the electronic device 10.

FIGS. 3B and 3C are similar to FIG. 3A, with the differences being which devices are connected to the electronic device 10 and to which ports the devices are connected to the electronic device 10. The operating conditions disclosed in FIG. 3A are also applicable to FIGS. 3B and 3C, possibly with necessary modifications that are within the level of persons having ordinary skill in the art.

No charger 70 is connected to the electronic device 10 in the scenarios depicted in FIGS. 3A-3C. The devices 30, 41 and 50 may draw power from the battery 20 of the electronic device 10. In some embodiments, the electronic device 10 may be said to operate in a “power bank mode” in the scenarios depicted in FIGS. 3A-3C.

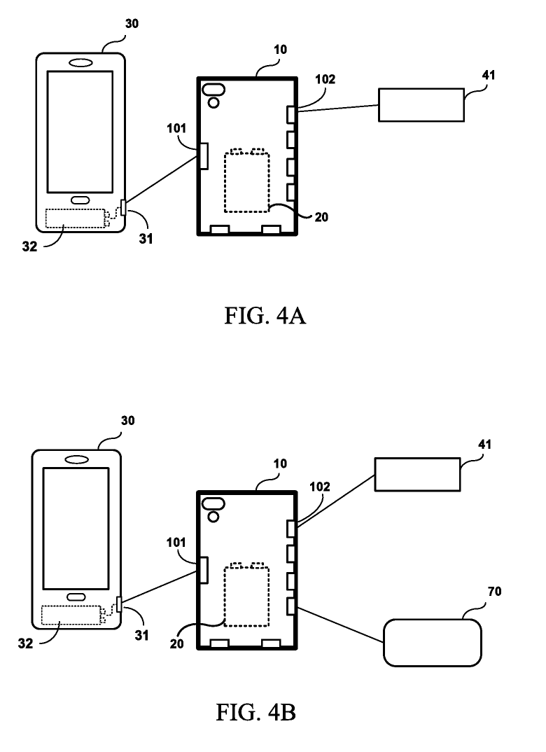

FIGS. 4A and 4B depict yet other possible usage scenarios of the electronic device 10.

Refer to FIG. 4A, where a device 30 is connected to the port 101 and a device 41 is connected to the port 102. In accordance with an embodiment of the present disclosure, the device 30 may be a host device comprising a port 31 and an internal battery 32, such as a smartphone or a tablet. In accordance with an embodiment of the present disclosure, the device 41 may be a peripheral device that requires an external power source to operate. In some embodiments, the device 41 is a USB memory stick or a keyboard. In some embodiments, devices other than the device 41 are connected to the ports 102. In the embodiment depicted in FIG. 4A, the electronic device 10 may expand the connection capability of the port 31 of the host device 30. The electronic device 10 may also supply power, by way of the battery 20, to the host device 30 and the peripheral device 41. The embodiment depicted in FIG. 4A differs from a simple hub device, where the peripheral device 41 has to draw power from the host device 30. By eliminating the need for supplying power from the host device 30 to the peripheral device 41, the electronic device 10 may save the power of the internal battery 32 of the host device 30. By being able to supply power to both the host device 30 and the peripheral device 41, the electronic device 10 may keep the host device 30 operating even when the internal battery 32 is low on power.

FIG. 4B differs from FIG. 4A in that a charger 70 is additionally connected to the electronic device 10. In accordance with an embodiment of the present disclosure, the device 30 may be a host device comprising a port 31 and an internal battery 32, such as a smartphone or a tablet. In accordance with an embodiment of the present disclosure, the device 41 may be a peripheral device that requires an external power source to operate. In some embodiments, the device 41 is a USB memory stick or a keyboard. In some embodiments, devices other than the device 41 are connected to the ports 102. The charger 70 provides an additional choice of power sources that may supply power to the devices 30 and 41. The charger 70 may charge the battery 20 of the electronic device 10.

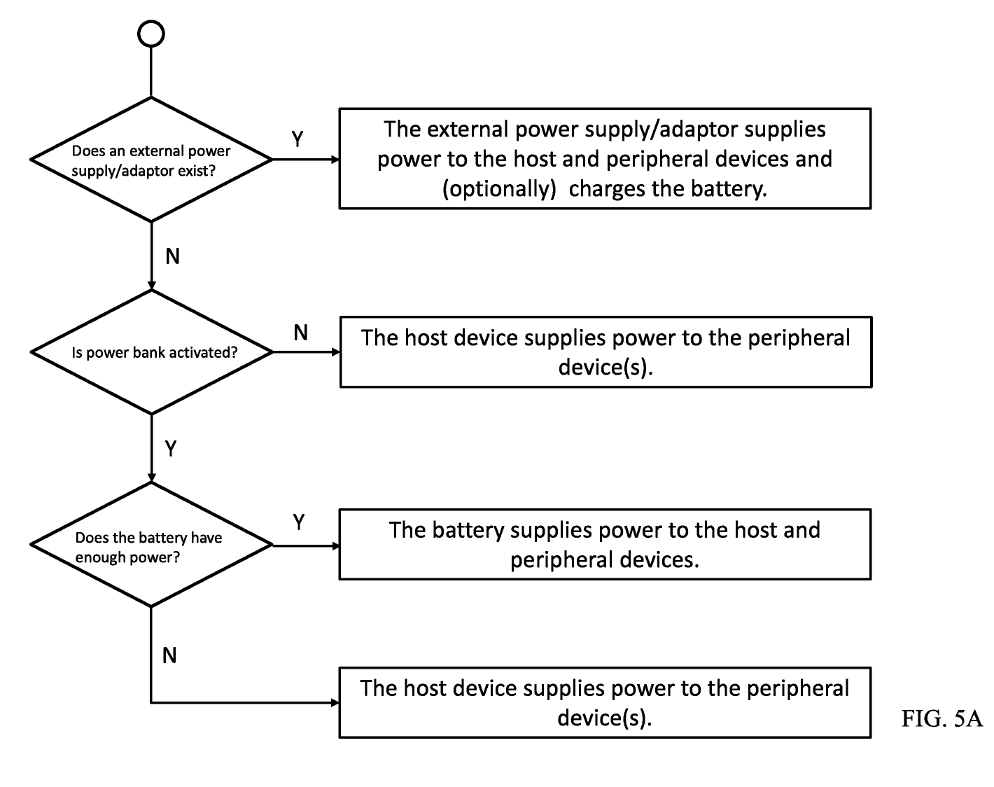

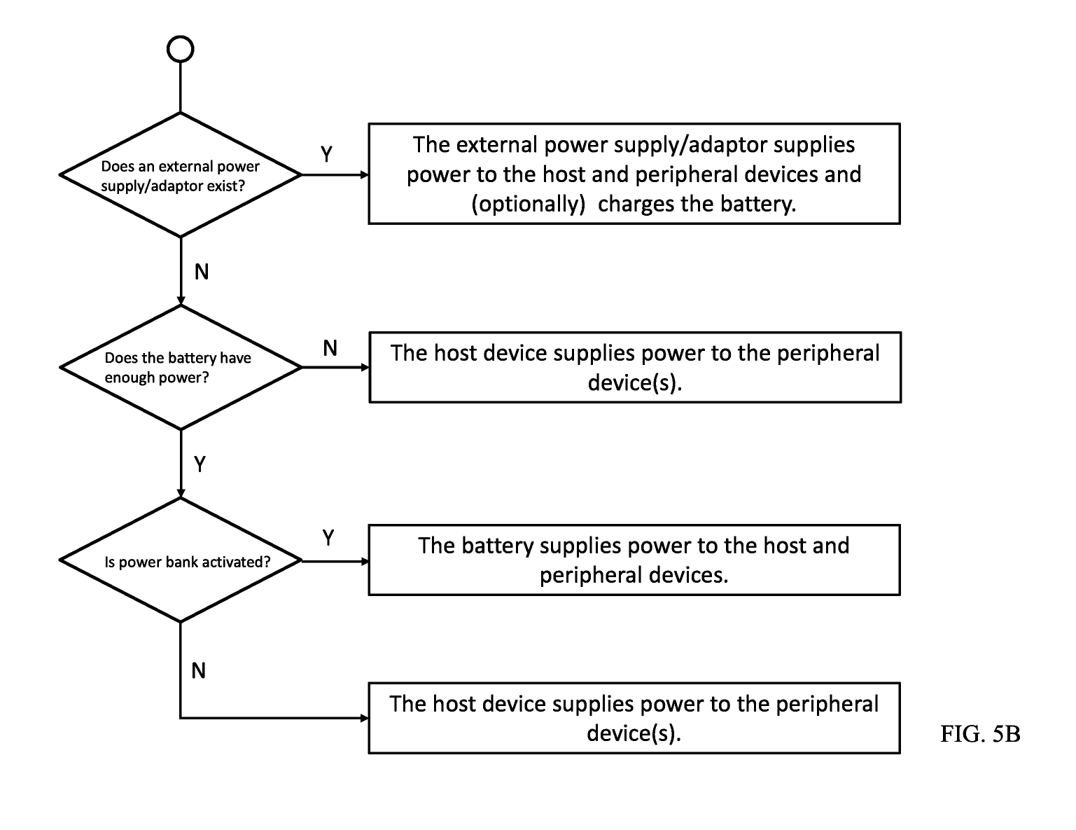

In the scenarios depicted in FIGS. 4A and 4B, more than one source of power is available, such as the battery 20 of the electronic device 10, the internal battery 32 of the device 30, and the charger 70. FIG. 5A illustrates an exemplary method to determine which power source is used to power/charge which device in accordance with an embodiment of the present disclosure.

Refer to FIG. 5A. The electronic device 10 first determines whether a charger or an external power supply is connected. If one exists, the charger/external power supplies power to the devices connected to the electronic device 10 and may optionally charge the battery 20 of the electronic device 10. Drawing power from the external power supply whenever possible has the benefit of conserving the internal battery of the host device and the battery 20 of the electronic device 10, thereby increasing the length of time the host device can run on its own internal battery and the amount of power that the battery 20 of the electronic device 10 can supply.

If no charger or external power supply exists, then the electronic device 10 determines whether its battery 20 is activated (by means of, e.g., the activation tool 311). If it is not activated, then the charging of the electronic device 10 is not activated, and devices without their own sources of power (such as a keyboard or a mouse) may draw power from devices that have their own sources of power (such as a smartphone, a laptop or a tablet).

If the battery 20 is activated, then the electronic device 10 determines whether the battery 20 has sufficient power. If this is the case, then the devices connected to the electronic device 10 may draw power from the battery 20.

If the battery 20 is activated but the battery 20 does not have sufficient power, then the charging function of the electronic device 10 is not activated, and devices without their own sources of power (such as a keyboard or a mouse) may draw power from devices that have their own sources of power (such as a smartphone, a laptop or a tablet).

FIG. 5B illustrates an exemplary method to determine which power source is used to power/charge which device in accordance with an embodiment of the present disclosure.

The first step is, similar to FIG. 5A, to determine the existence of a charger or an external power supply connected to the electronic device 10. Making this determination early allows better conservation of the battery of the devices connected to the electronic device 10.

Afterwards, the electronic device 10 determines whether the battery 20 has sufficient power. If not, then devices without their own sources of power (such as a keyboard or a mouse) may draw power from devices that have their own sources of power (such as a smartphone, a laptop or a tablet). In some embodiments, the signaling unit 321 would indicate a low battery level, informing the user of this situation and prompting the user to charge the battery 20 of the electronic device 10.

If the battery 20 has sufficient power, then the electronic device 10 determines whether the charging function of the electronic device 10 is activated (by means of, e.g., the activation tool 311). If it is activated, then the devices connected to the electronic device 10 may draw power from the battery 20. If it is not activated, then devices without their own sources of power (such as a keyboard or a mouse) may draw power from devices that have their own sources of power (such as a smartphone, a laptop or a tablet).

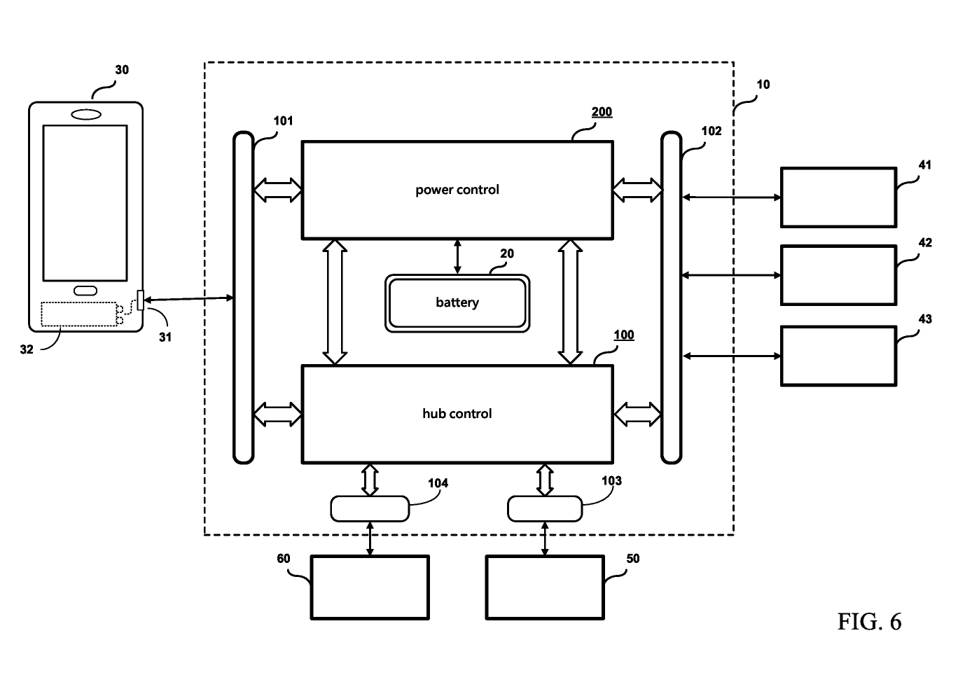

FIG. 6 illustrates a more detailed block diagram of the electronic device 10 in accordance with some embodiments of the present disclosure. In addition to the ports 101, 102, 103, 104 and the battery 20, the electronic device 10 comprises a hub control unit 100 and a power control unit 200. The battery 20 is connected to the power control unit 200. The hub control unit 100 is connected to the ports 101-104 and the power control unit 200. The power control unit 200 is connected to the battery 20, the hub control unit 100, and ports 101 and 102. In some embodiments, the power control unit 200 may also be connected to ports 103 and 104.

The hub control unit 100 provides data communication among the connected ports. The hub control unit 100 may provide a hub function. The hub control unit 100 may provide data multiplexing/de-multiplexing function. In some embodiments, the hub control unit 100 is based on standardized specifications, such as the USB specifications.

The power control unit 200 provides power communication among the connected ports, battery and blocks. In some embodiments, the power control unit 200 may send and receive a plurality of identical, similar or different power signals among the connected ports, battery and blocks. The plurality of power signals may be at different voltages such as 0V, 1V, 2V, 3V, 4V, 5V, 6V, 7V, 8V, 9V, 10V, 11V, 12V, 13V, 14V, 15V, 16V, 17V, 18V, 19V, 20V, any suitable voltages above 20V, and any suitable non-integer voltages. The plurality of power signals may have any suitable amount of currents or power. The plurality of power signals may be in different voltage ranges. In some embodiments, the power control unit 200 may provide data communication. In some embodiments, the hub control unit 100 is based on standardized specifications, such as the USB specifications and the USB PD specifications. In accordance with an embodiment of the present disclosure, the power control unit 200 may receive one or more power signals from the battery 20 and transmit the received power signal(s) to any of the connected ports and blocks. The power control unit 200 may transmit power signals at various different voltages, such as at voltages different from the power signals received from the ports 101, 102 or the battery 20. The power control unit 200 may detect what is connected to the ports to which the battery 20 is connected. The power control unit 200 may detect the status of the battery 20, such as the battery level.

The operation of the usage scenarios of FIGS. 2A, 2B, 2C, 2D, 2E, 2F, 3A, 3B, 3C, 4A and 4B may be further explained with the embodiment of FIG. 6.

In the usage scenario of FIG. 2A, the power control unit 200 may determine whether to charge the battery 20. If yes, the power signal may flow from the charger 70 to the power control unit 200 via the port 101, and then the power control unit 200 may direct the power signal to the battery 20. When receiving the power signal from the port 101, the power control unit 200 may make modifications or changes to the power signal before directing it to the battery 20. The modifications or changes may relate to any suitable electrical characteristics, such as voltage, current, power, frequency, duty cycle, etc. In some embodiments, the power control unit 200 may determine that the battery 20 does not have to be charged, in which case the charger 70 may choose to not output a power signal or the power control unit 200 may cut off the power signal received from the port 101.

The usage scenario of FIG. 2B is similar to that of FIG. 2A, except that the charger 70 is connected to port 102. Since the ports 101 and 102 may have similar capabilities, the above explanation regarding FIG. 2A is also applicable to FIG. 2B and thus not repeated.

In the usage scenario of FIG. 2C, the power control unit 200 may determine whether to charge the battery 20. If yes, the power signal may flow from the charger 70 to the power control unit 200 via the port 102, and then the power control unit 200 may direct the power signal to the battery 20. When receiving the power signal from the port 102, the power control unit 200 may make modifications or changes to any suitable electrical characteristics of the power signal, such as voltage, current, power, frequency, duty cycle, etc. In some embodiments, the power control unit 200 may determine that the battery 20 does not have to be charged, in which case the charger 70 may choose to not output a power signal. In some embodiments, the power control unit 200 or the device 30 may determine that the device 30 receive power from the charger 70. In this case, the power control unit 200 transmits a power signal to the port 101 based on the power signal received from the charger 70. Again, the power control unit 200 may modify any electrical characteristics of the power signal received from the charger 70 and to suit the needs of the power signal transmitted to the port 101. In some embodiments, the battery 20 may provide power to the device 30 in addition to or in lieu of the charger 70.

The usage scenario of FIG. 2D is similar to that of FIG. 2C, except that a charger 70 is connected to the port 101 and a device 41 without its own battery is connected to the port 102. Thus, the power control unit 200 may additionally determine whether power will be drawn from the battery 20 to supply the device 41.

The usage scenario of FIG. 2E is similar to that of FIG. 2D. In some embodiments, the ports 101, 102, 103 have different specifications or capabilities and thus the electrical characteristics of the power signals each of the ports 101, 102, 103 can handle may be different. The power control unit 200 would then make any necessary modifications to the received power signals and then transmit the modified power signals.

The usage scenario of FIG. 2F differs from that of FIGS. 2D and 2E in that more than one device is connected to the electronic device 10. The power control unit 200 may output more than one power signal to different devices by, for example, drawing more power from the charger 70 or drawing additional power from the battery 20 or both.

In the scenarios of FIGS. 2A-2F, the power control unit 200 may determine whether to draw power from the charger 70, whether to charge or draw power from the battery 20, and how to output power signals with electrical characteristics that suit the power supply requirements of the devices connected to the electronic device 10. An advantage of the power control unit 200 is the flexibility in using/charging the battery 20 to make the best use of it and extend the lifetime of the battery 20. Another advantage is the ability to supply power to many devices that may have different power supply requirements.

The power control unit 200 may use different methods to determine whether to charge or draw power from the battery 20. In some embodiments, the power control unit 200 may detect the amount of power available in the battery 20. In some embodiments, the power control unit 200 may detect the amount of voltage or current that the battery 20 is able to output.

None of the scenarios of FIGS. 3A-3C involves a charger 70. The power control unit 200 determines the level of the battery 20, and supply power signals with potentially different electrical characteristics to meet the needs of the different devices connected to the electronic device 10 and the different capabilities of the ports of the electronic device 10. In some embodiments, such as illustrated in FIG. 3A, the power control unit 200 checks whether the activation tool 311 has been triggered in determining whether to draw power from the battery 20.

In the usage scenario of FIG. 4A, the devices 30, 41 are connected to the electronic device 10. The power control unit 200 may determine whether to draw power from the battery 20 based on the factors described above. The power control unit 200 may determine whether to supply power to the device 30. The power control unit 200 may determine whether to let the device 30 supply power to the device 41 or let the battery 20 supply power to the device 41; in some embodiments, the determination may be at least partly based on the methods illustrated in FIGS. 5A and 5B. The power control unit 200 may change the electrical characteristics of the received power signals. The power control unit 200 may convert the electrical characteristics of the received power signals and transmit the converted power signals to the battery 20, the hub control unit 100, or any of the ports. In some embodiments, such as the one depicted in FIG. 1, other devices may be connected to the electronic device 10, and the hub control unit 100 handles the data communication among the connected devices.

The usage scenario of FIG. 4B differs from that of FIG. 4A in that a charger 70 is additionally connected to the electronic device 10. Based on the factors described above, the power control unit 200 may determine whether to use or charge the battery 20, whether to draw power from or charge the device 30, whether to draw power from the charger 70, and which power source(s) to use to charge the device 41. In some embodiments, the determination may be at least based on the methods illustrated in FIGS. 5A and 5B. The power control unit 200 may change the electrical characteristics of the received power signals. The power control unit 200 may convert the electrical characteristics of the received power signals and transmit the converted power signals to the battery 20, the hub control unit 100, or any of the ports.

The power control unit 200 may use different methods to determine which power source(s) to use. In some embodiments, the power control unit 200 may detect the electrical characteristics of the output of the battery 20. The battery 20 may choose to first draw power from the charger 70 whenever available to conserve power stored in the battery 20 and/or the internal battery 32 of the device 30. The power control unit 200 may also consider the user's input, such as whether the activation tool 311 has been touched. In some embodiments, the power control unit 200 may compare the voltage of the output of the battery 20 to a threshold. In some embodiments, the power control unit 200 may compare the voltage of the output of the battery 20 and the voltage of the power signal provided by the device 30. In some embodiments, the power control unit 200 may determine that the battery 20 has sufficient power if the voltage of the output of the battery 20 is more than the voltage of the power signal received at one of the ports. In some embodiments, the power control unit 200 may determine that the battery 20 has sufficient power if the difference between the voltage of the output of the battery 20 and the voltage of the power signal received at one of the ports is within a predetermined or adaptive threshold.

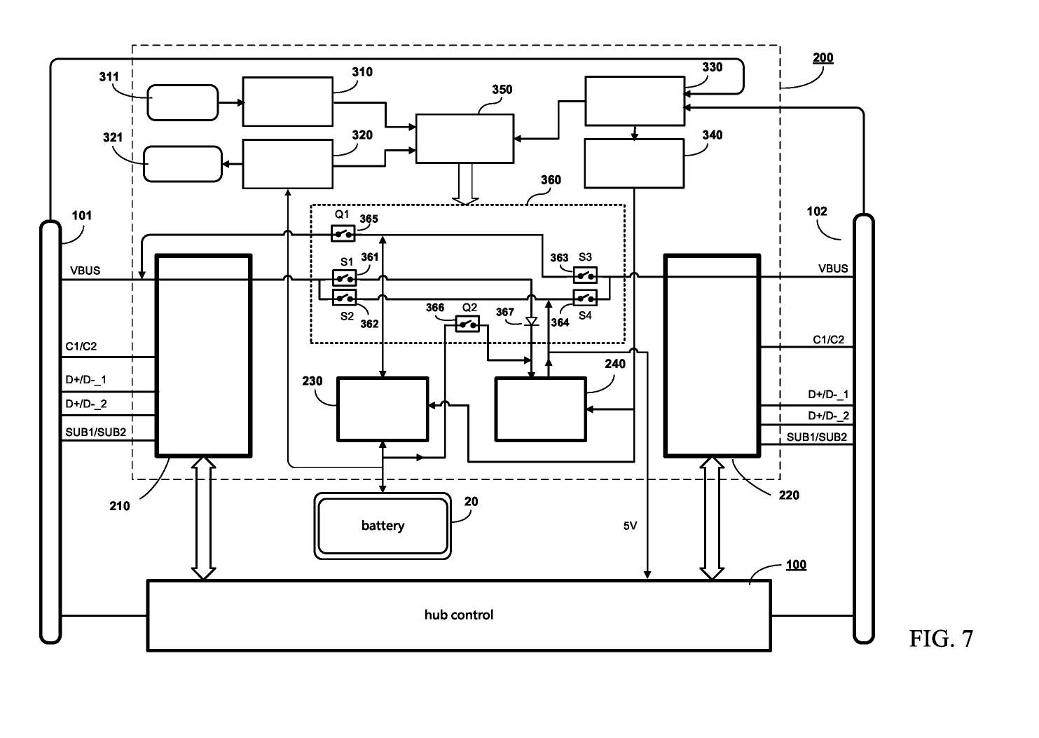

FIG. 7 illustrates an electronic device in accordance with some embodiments of the present disclosure.

The power control unit 200 comprises a power delivery control unit 210, a power delivery control unit 220, a voltage conversion unit 230, a voltage conversion unit 240, a mode setting unit 310, an activation tool 311, a monitor unit 320, a signaling unit 321, a detection unit 330, a voltage setting unit 340, a switching control unit 350 and a switch module 360. Persons having ordinary skill in the art would appreciate that the interconnection shown in FIG. 7 is merely exemplary and not limiting.

The power delivery control unit 210 is connected to the port 101 and may determine whether and how to transmit and receive signals, such as data signals and power signals. The power delivery control unit 210 may be connected to the hub control unit 100 and may deliver power thereto. The power delivery control unit 210 may be connected to the switch module 360. The power delivery control unit 210 may have a bus. The bus may have pins that at least partially match the pins of the port 101. The power delivery control unit 210 may support a standardized specification, with possibly different versions. In some embodiments, the power delivery control unit 210 may be based on USB. In some embodiments, the power delivery control unit 210 may support USB 3.0. In some embodiments, the power delivery control unit 210 may support USB 3.0 Type-C Power Delivery (PD). In some embodiments, the bus of the power delivery control unit 210 may have the pins of (VBUS, C1/C2, D+/D−_1, D+/D−_2, SUB1/SUB2) connectable to the port 101.

The power delivery control unit 220 is similar to the power delivery control unit 210 and thus will not be discussed in detail.

The voltage conversion unit 230 may be connected to the battery 20. The voltage conversion unit 230 may be connected to the switch module 360. The voltage conversion unit 230 may be connected to the monitor unit 320. The voltage conversion unit 230 may receive an electrical signal, such as a power signal, at one voltage and convert the electrical signal to another voltage. The voltage conversion unit 230 may receive and transmit electrical signals in a voltage range. The voltage range may be any suitable range. In some embodiments, the voltage range is from 5V to 20V. The voltage conversion unit 230 may operate at a fixed nominal voltage, such as 5V; in which case the voltage conversion unit 230 may provide functions other than voltage conversion, such as signal isolation and impedance transformation. The voltage conversion unit 230 may be a converter or a voltage regulator. In some embodiments, the voltage conversion unit 230 may be a DC-DC converter, such as a buck-boost DC-DC converter. The input/output voltage of the voltage conversion unit 230 may be based on parameters supplied by another block, such as the voltage setting unit 340.

The voltage conversion unit 240 may be connected to the switch module 360. The voltage conversion unit 240 may be connected to the hub control unit 100. In some embodiments, the voltage conversion unit 240 may power the hub control unit 100. The voltage conversion unit 240 may receive an electrical signal, such as a power signal, at one voltage and convert the electrical signal to another voltage. The voltage conversion unit 240 may receive and transmit electrical signals in a voltage range. The voltage range may be any suitable range. In some embodiments, the voltage range is from 5V to 20V. The voltage conversion unit 240 may operate at a fixed nominal voltage, such as 5V; in which case the voltage conversion unit 240 may provide functions other than voltage conversion, such as signal isolation and impedance transformation. The voltage conversion unit 240 may be a converter or a voltage regulator. In some embodiments, the voltage conversion unit 240 may be a DC-DC converter, such as a buck DC-DC converter. The input/output voltage of the voltage conversion unit 240 may be based on parameters supplied by another block, such as the voltage setting unit 340.

The mode setting unit 310 may be connected to the activation tool 311. In some embodiments, the activation tool 311 indicates the activation of the battery 20. The mode setting unit 310 would then indicate such activation to the switching control unit 350, which in turn configures the switch module 360 such that the output of the battery 20 is transmitted, to any one of the ports, such as ports 101, 102. The mode setting unit 310 may decide which power source(s) to use to power which connected device(s). The mode setting unit 310 may be programmed or configured to practice the methods illustrated in FIGS. 5A and 5B.

The monitor unit 320 may monitor the status of the battery 20. The monitor unit 320 may monitor the level of the battery 20. The monitor unit 320 may be connected to the signaling unit 321 to indicate the status or level of the battery 20. The monitor unit 320 may be connected to the switching control unit 350 to affect the power signals entering or exiting the switch module 360. In some embodiments, if the monitor unit 320 determines that the battery 20 does not have sufficient power, the switching control unit 350 may configure the switch module 360 such that there is no direct or indirect electrical connection between the battery 20 and the ports 101, 102.

The detection unit 330 may be connected to any number of the ports of the electronic device 10, such as the port 101, the port 102 or both ports 101, 102. The detection unit 330 may be connected to the switching control unit 350 to configure the power signals based on the output of the detection unit 330. The detection unit 330 may detect whether data and/or power signals are present at the connected ports. The detection unit 330 may detect the electrical characteristics of the signals that are present at the connected ports, such as voltage, current and power. The detection unit 330 may detect whether the ports are connected to other devices, and what devices the ports are connected to. In some embodiments, the detection unit 330 may detect whether the connected devices support a standardized specification (and which version(s)), such as USB PD. The detection unit 330 may determine the type of the connected devices, such as host device, peripheral device, self-powered device, charger, etc. The detection unit 330 may be connected to the voltage setting unit 340 and may feed different outputs to the voltage setting unit 340 in responsive to the detected results.

The switching control unit 350 is connected to the switch module 360. The switching control unit 350 may be connected to other blocks whose output may affect the characteristics and flow of the power signals in the power control unit 200, such as the mode setting unit 310, the monitor unit 320 and the detection unit 330.

The switch module 360 comprises switches and is controlled and or configured by the switching control unit 350. The switch module 360 determines how the electrical signals in the power control unit 200 flow. The switch module 360 may comprise switch 361 (S1), switch 362 (S2), switch 363 (S3), switch 364 (S4), switch 365 (Q1) and switch 366 (Q2). In some embodiments, the switch module 360 may comprise a comparison unit 367 that compares the electrical characteristics of the signals coupled thereto.

S1 may be connected between the VBUS pin of the port 101 and the voltage conversion unit 240. S2 may be connected between the VBUS pin of the port 101 and the voltage conversion unit 240. S2 may be connected to S4. S3 may be connected between the VBUS pin of the port 102 and the voltage conversion unit 230. S3 may be connected to Q1. S4 may be connected between the VBUS pin of the port 102 and the voltage conversion unit 240. S4 may be connected to S2. Q1 may be connected between the VBUS pin of the port 101 and the voltage conversion unit 230. Q2 may be connected between the battery 20 and the voltage conversion unit 240. The comparison unit 367 may be connected between S1 and the voltage conversion unit 240. In some embodiments, the comparison unit 367 may compare electrical characteristics of the signal from S1 and the signal from the voltage conversion unit 240. The comparison unit 367 may have an output based on the comparison result.

In some embodiments, the comparison unit 367 may be a voltage comparator. In some embodiments, the comparison unit 367 may be an operational amplifier. In some embodiments, the comparison unit 367 may be an asymmetric conductance device.

In some embodiments, the comparison unit 367 may be a diode. In some embodiments, the anode (positive terminal) may be connected to S1, and the cathode (negative terminal) may be connected to the voltage conversion unit 240. In some embodiments, the diode may have a voltage drop, such as 0.7V. The power signal from S1 may pass the diode if its voltage is higher than the voltage at a terminal of the voltage conversion unit 240 by the voltage drop. In an embodiment where Q2 is closed, then the diode would become forward biased if the voltage coming from S1 is higher the voltage of the battery 20 (by the voltage drop if it exists). In other words, the diode may determine whether it is the power signal from the battery 20 or the VBUS pin of the port 101 that goes to the voltage conversion unit 240. In other words, the diode may determine which power source powers the voltage conversion unit 240, the battery 20 or the device connected to the port 101.

The operation of the usage scenarios of FIGS. 2A, 2B, 2C, 2D, 2E, 2F, 3A, 3B, 3C, 4A and 4B may be further explained with the embodiment of FIG. 7.

In the usage scenario of FIG. 2A, Q1 may be closed and the charger 70 may charge the battery 20 by way of the voltage conversion unit 230. In the usage scenario of FIG. 2B, S3 may be closed and the charger 70 may charge the battery 20 by way of the voltage conversion unit 230.

In the usage scenario of FIG. 2C, Q1 and S3 may be closed. The charger 70 may charge the battery 20 by way of the voltage conversion unit 230. The charger 70 may charge the device 30. The power delivery control unit 220 may modify the power signal of the charger 70 before it reaches the device 30.

In the usage scenario of FIG. 2D, Q1 and S3 may be closed. The charger 70 may charge the battery 20 by way of the voltage conversion unit 230. The charger 70 may charge the device 41. The power delivery control unit 210 or the power delivery control unit 220 may modify the power signal of the charger 70 before it reaches the device 41.

In the usage scenario of FIG. 2E, Q1 and S1 may be closed. The charger 70 may charge the battery 20 by way of the voltage conversion unit 230. The charger 70 may power the device 50 by way of the voltage conversion unit 240 and the hub control unit 100.

In the usage scenario of FIG. 2F, Q1, S1 and S3 may be closed. The charger 70 may charge the battery 20 by way of the voltage conversion unit 230. The charger 70 may power the device 41. The power delivery control unit 210 or the power delivery control unit 220 may modify the power signal of the charger 70 before it reaches the device 41. The charger 70 may power the device 50 by way of the voltage conversion unit 240 and the hub control unit 100.

In some other usage scenarios, Q1, S1 and S3 may be closed. The operations described with respect to FIGS. 2E and 2F are also applicable.

In the usage scenario of FIG. 3A, Q1 may be closed. The battery 20 may charge the device 30 by way of the voltage conversion unit 230. In some embodiments, Q2 and S2 may be closed to let the battery 20 charge the device 30 by way of the voltage conversion unit 240. Since the voltage conversion unit 230 and the voltage conversion unit 240 may have different output voltage ranges, the switch module 360 may enable the electronic device 10 to charge devices with a variety of different voltage requirements.

In the usage scenario of FIG. 3B, S3 may be closed. The battery 20 may charge the device 41 by way of the voltage conversion unit 230. In some embodiments, Q2 and S4 may be closed to let the battery 20 charge the device 41 by way of the voltage conversion unit 240. This arrangement could enable the electronic device 10 to charge devices with a variety of different voltage requirements.

In the usage scenario of FIG. 3C, Q2 may be closed. The battery 20 may charge the device 50 by way of the voltage conversion unit 240 and the hub control unit 100.

In the usage scenario of FIG. 4A, Q1, Q2 and S4 may be closed, and S1, S2 and S3 may be open. This may make the battery 20 charge the device 30 by way of the voltage conversion unit 230 and charge the device 41 by way of the voltage conversion unit 240. This arrangement could enable the electronic device 10 to charge devices with a variety of different voltage requirements. In some embodiments, the power control unit 200 may decide to let the device 30 power the device 41, in which case Q1 and S3 may be closed and the voltage conversion unit 230 may be deactivated by the voltage setting unit 340.

In the usage scenario of FIG. 4B, Q1, Q2 and S3 may be closed. The charger 70 may charge the battery 20 by way of the voltage conversion unit 230. The charger 70 may power the device 41 by way of the power delivery control unit 220. The charger 70 may power the device 30 directly or by way of the power delivery control unit 210 or the power delivery control unit 220. S1 may be closed to feed the power signal from the charger 70 to the voltage conversion unit 240.

Embodiments of the present disclosure provide a multi-functional device that may combine the function of a hub and a power bank, giving the user more convenience. Embodiments of the present disclosure provide methods to determine which power source to use to power/charge which devices when more than one power source present. Embodiments of the present disclosure help conserve the battery level of the multi-functional device and the battery level of self-powered mobile devices. The multi-functional device according to the embodiments of the present disclosure may supply power to a variety of devices with different electrical requirements.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations do not limit the present disclosure. It can be clearly understood by those skilled in the art that various changes may be made, and equivalent components may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. An apparatus, comprising:
a first port;
a second port;
a battery;
a power control unit electrically connected to the battery, the first port and the second port, wherein the power control unit is configured to, on the basis of an output from the battery:
transmit a first power signal to the first port and transmit a second power signal to the second port; or
transmit a third power signal received by the first port to the second port.

2. The apparatus of claim 1, wherein the first power signal has a first voltage, the second power signal has a second voltage, the third power signal has a third voltage at the first port and the third power signal is converted to have a fourth voltage and transmitted to the second port.

3. The apparatus of claim 2, wherein the second voltage differs from the first voltage and the fourth voltage differs from the third voltage.

4. The apparatus of claim 1, wherein the power control unit is configured to determine whether the output from the battery is greater than a first threshold.

5. The apparatus of claim 4, wherein the power control unit is configured to transmit the first power signal to the first port and transmit the second power signal to the second port if the output from the battery is greater than or substantially equal to the first threshold.

6. The apparatus of claim 4, wherein the power control unit is configured to transmit the third power signal received by the first port to the second port if the output from the battery is less than the first threshold.

7. The apparatus of claim 4, wherein the power control unit comprises a comparison unit having a first terminal and a second terminal, wherein the first terminal is electrically connected to the first port or the second port and the second terminal is electrically connected to the output from the battery.

8. The apparatus of claim 7, wherein the first threshold is substantially equal to a difference between the third voltage and an offset voltage of the comparison unit.

9. The apparatus of claim 1, wherein the power control unit comprises a switch module electrically connected to the first port, the second port and the battery.

10. The apparatus of claim 1, further comprising a hub control unit controlling data communication between the first port and the second port.

11. The apparatus of claim 1, wherein the third power signal is provided by an external power supply and the power control unit is configured to charge the battery with the third power signal.

12. The apparatus of claim 1, wherein the power control unit comprises a detection module configured to detect a connection state of the first port.

13. The apparatus of claim 1, wherein the power control unit comprises a detection module configured to detect a connection state of the second port.

14. An apparatus, comprising:
a first port;
a second port;
a power control unit electrically connected to the first port and the second port;
a battery electrically connected to the power control unit;
a hub control unit electrically connected to the first port, the second port and the power control unit;
wherein the power control unit outputs a first voltage to the first port and a second voltage different from the first voltage to the second port.

15. The apparatus of claim 14, wherein the power control unit comprises a first voltage conversion unit operable at a first voltage range and a second voltage conversion unit operable at a second voltage range.

16. The apparatus of claim 15, wherein the first voltage conversion unit is electrically connected to the battery.

17. The apparatus of claim 15, wherein the second voltage conversion unit is coupled to the first voltage conversion unit and the second voltage range is different from the first voltage range.

18. The apparatus of claim 14, wherein the power control unit comprises a switch module and a switching control unit coupled to the switch module, wherein the switch module is electrically connected to the battery, the first port and the second port, wherein the switching control unit determines the first voltage and the second voltage.

19. The apparatus of claim 14, wherein the hub control unit is a USB hub control unit.

20. The apparatus of claim 19, wherein the hub control unit is a USB 3.0 hub control unit.

21. The apparatus of claim 14, further comprising a detection module electrically connected to the first port.

22. The apparatus of claim 21, wherein the first voltage is determined at least in part based on the detection module.

23. The apparatus of claim 14, further comprising a detection module electrically connected to the second port.

24. The apparatus of claim 23, wherein the second voltage is determined at least in part based on the detection module.

25. The apparatus of claim 14, wherein the power control unit comprises a monitor circuitry electrically connected to the battery, wherein the first voltage and the second voltage are determined based on an output from the monitor circuitry.
